(19) United States
(12) Patent Application Publication
(10) Pub. No.: US 2010/0096008 A1
(43) Pub. Date: Apr. 22, 2010

(54) SEMITRANSPARENT CRYSTALLINE SILICON THIN FILM SOLAR CELL

(75) Inventor: Byoung Su Lee, Yeosu-si (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/524,337

(22) PCT Filed: Dec. 21, 2007
(86) PCT No.: PCT/KR2007/006725

§ 371 Date: Jul. 23, 2009

(30) Foreign Application Priority Data
Jan. 30, 2007 (KR) 10-2007-009214

(51) Int. Cl. H01L 31/00

(52) U.S. Cl. 136/256

(57) ABSTRACT

Provided is a semitransparent crystalline silicon thin film solar cell using a crystalline silicon thin film, including a transparent substrate, an antireflection layer, first transparent electrodes, electricity generation regions, second transparent electrodes, insulating layers. The electricity generation regions include crystalline silicon thin films. Accordingly, the semitransparent crystalline silicon thin film solar cell has a simpler manufacturing process as compared with a semitransparent thin film solar cell using a conventional amorphous thin film and can control transmittance by controlling a thickness of the crystalline thin film without additional apparatuses.

### BACKGROUND OF THE INVENTION

1. Field of the Invention

The present invention relates to a solar cell, and more particularly, to a semitransparent crystalline silicon thin film solar cell which has a similar structure to that of a conventional opaque thin film solar cell and uses a crystalline silicon thin film for an electricity generation region to simplify a manufacturing method and reduce a manufacturing time.

2. Description of the Related Art

A semitransparent solar cell is mainly used as a material of windows or roofs of buildings and has been widely developed and applied as a core material of a system that can satisfy a fine view and energy acquisition. Specifically, portions of external light are transmitted to see external circumstances from the inside of the buildings, and portions of light that are not transmitted are used for a solar power system.

FIG. 1 is a view illustrating a structure of a conventional semitransparent thin film solar cell.

Referring to FIG. 1, the conventional semitransparent thin film solar cell includes a transparent glass substrate 110, an antireflection layer 120 formed on the transparent glass substrate 110, first transparent electrodes 131 and 132 and solar cells 141 and 142 formed on the antireflection layer 120, and second transparent electrodes 151 and 152 formed thereon. In addition, as needed, insulating layers 161 and 162 for insulating the cells from the electrodes may be formed. The aforementioned structure is a structure of a general thin film solar cell, and for semitransparency of the general thin film solar cell, a ratio of a region 180 where the two transparent electrodes are connected to each other to regions 171 and 172 where electricity generation occurs is controlled to control light transmittance.

For example, when a transmittance of 10% is required, a ratio of the transparent region 180 to the non-transparent regions 171 and 172 is controlled to be 1:9. In this case, in order to see things through transmitted light, intervals between the transparent regions 180 have to be dense. Therefore, in most cases, the intervals between the transparent regions are less than several mm.

For the dense intervals between the transparent regions, a fine pattern has to be formed, and this causes increases in a manufacturing time and manufacturing costs of the semitransparent solar cell.

When the pattern is formed by using a laser scriber and an interval between the transparent region and the semitransparent region is 1 mm, in order to manufacture the semitransparent solar cell having a length of 1 m, 1000 or more times of operations have to be performed by the laser scriber to form lines. As compared with a case where about 100 times of operations are performed by the laser scriber to form lines in order to manufacture an opaque thin film solar cell having an interval of 1 cm or less between cells and a length of 1mm, more apparatuses and 10 or more times the manufacturing time are required for the laser scriber needed to manufacture the opaque thin film solar cell.

### SUMMARY OF THE INVENTION

The present invention provides a semitransparent crystalline silicon thin film solar cell which has a similar structure to that of a non-transparent thin film solar cell and uses a crystalline silicon thin film for an electricity generation region to simplify a manufacturing method and reduce a manufacturing time.

According to an aspect of the present invention, there is provided a semitransparent crystalline silicon thin film solar cell including: an antireflection layer formed on a transparent substrate; first transparent electrodes formed on the antireflection layer; electricity generation regions formed on the first transparent electrodes; second transparent electrodes formed on the electricity generation regions; and insulating layers insulating the first transparent electrodes, the electricity generation regions, and the second transparent electrodes from each other, wherein the electricity generation regions includes crystalline silicon thin films.

The semitransparent crystalline silicon thin film solar cell uses a crystalline silicon thin film as a device of the solar cell. The crystalline thin film silicon has low optical absorption property as compared with amorphous silicon used for a general thin film solar cell. For red light having energy of 2.2 eV, an absorption coefficient of monocrystalline silicon is 6×10³/cm, and an absorption coefficient of amorphous silicon is 4×10⁴/cm. For green light having energy of 2.6 eV, an absorption coefficient of the monocrystalline silicon is 3×10⁴/cm, and an absorption coefficient of the amorphous silicon is 2×10⁵/cm.

When light passes through a medium having a refractive index of n₁, an absorption coefficient of a, and a length of L and is incident on a medium having a refractive index of n₂, transmittance can be obtained by Equation 1 as follows.

$$T ∝ \frac{2 {n}_{1}}{( {n}_{1} + {n}_{2} )} exp ( - α L ) \qquad [ Equation 1 ]$$

When transmittance of red light is calculated by using Equation 1, transmittance of the red light transmitted by a layer including an amorphous thin film having a thickness of 1 μm and tin-oxide (SnO) is about 8%, and transmittance of the red light transmitted by a layer including a crystalline thin film having a thickness of 1 μm and the tin-oxide SnO is about 50%. According to the present invention, aforementioned characteristics of the crystalline silicon are used.

### BRIEF DESCRIPTION OF THE DRAWINGS

FIG. 1 is a view illustrating a structure of a conventional semitransparent thin film solar cell.

FIG. 2 is a view illustrating a structure of a semitransparent crystalline silicon thin film solar cell according to an embodiment of the present invention.

### DETAILED DESCRIPTION OF PREFERRED EMBODIMENTS

Hereinafter, exemplary embodiments of the present invention will be described in detail with reference to the attached drawings.

FIG. 2 is a view illustrating a structure of a semitransparent crystalline silicon thin film solar cell according to an embodiment of the present invention.

Referring to FIG. 2, the semitransparent crystalline silicon thin film solar cell according to the embodiment of the present invention includes a transparent substrate 210, an antireflection layer 220 formed on the transparent substrate 210, first transparent electrodes 231 and 232 formed on the antireflection layer 220, and crystalline solar cell regions 241 and 242 and second transparent electrodes 251 and 252 formed on the first transparent electrodes 231 and 232. In addition, for insulating the cells from the electrodes, insulating layers 261 and 262 are formed. In general, since transparent electrodes have high electric resistances, in order to decrease contact resistances, a conductive layer 270 may be formed. In the aforementioned structure, light transmitted by the transparent substrate 210 passes though the antireflection layer 220 and is incident on the crystalline solar cell regions 241 and 242. Portions of the incident light are transmitted by the crystalline solar cell regions 241 and 242 that are crystalline silicon layers, and remaining portions thereof are thoroughly transmitted by the second transparent electrodes 251 and 252.

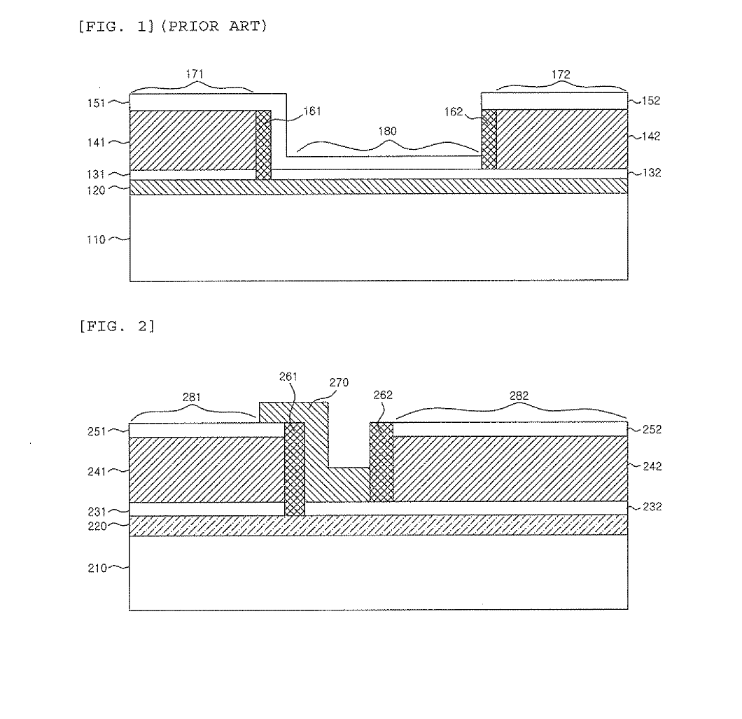

Therefore, regions 281 and 282 where semitransparency of light occurs in the aforementioned structure are aligned with the solar cell regions. Therefore, as compared with the general semitransparent solar cell as illustrated in FIG. 1, an interval between cells can be increased. In addition, when the conductive layer 270 covers the entire surface, the semitransparent crystalline silicon thin film solar cell can be used as an opaque thin film solar cell. Therefore, without forming a pattern using an additional laser scriber, the semitransparent crystalline silicon thin film solar cell can be manufactured by using the structure the same as that of the opaque thin film solar cell. In addition, by controlling a thickness of a crystalline thin film, light transmittance can be controlled.

The semitransparent crystalline silicon thin film solar cell uses a crystalline silicon thin film to increase transmittance, so that a manufacturing process is simple as compared with a manufacturing process of a semitransparent thin film solar cell using an amorphous thin film. In addition, a manufacturing process the same as that of an opaque solar cell is used, so that additional apparatuses are not needed. In addition, transmittance can be controlled by controlling a thickness of a crystalline thin film, so that unlike the semitransparent thin film solar cell using the amorphous thin film, the manufacturing process does not to be changed according to transmittance.

While the present invention has been particularly shown and described with reference to exemplary embodiments thereof, it will be understood by those skilled in the art that various changes in form and details may be made therein without departing from the spirit and scope of the present invention as defined by the appended claims.

1. A semitransparent crystalline silicon thin film solar cell comprising:
an antireflection layer formed on a transparent substrate;
first transparent electrodes formed on the antireflection layer;
electricity generation regions formed on the first transparent electrodes;
second transparent electrodes formed on the electricity generation regions; and
insulating layers insulating the first transparent electrodes, the electricity generation regions, and the second transparent electrodes from each other,
wherein the electricity generation regions include crystalline silicon thin films.

2. The semitransparent crystalline silicon thin film solar cell of claim 1, wherein the electricity generation region controls transmittance by controlling a thickness of the crystalline silicon thin film.

3. The semitransparent crystalline silicon thin film solar cell claim 1, further comprising a conductive layer electrically connecting the second transparent electrode to a first transparent electrode of an adjacent cell.

4. The semitransparent crystalline silicon thin film solar cell of claim 3, wherein a size of the conductive layer is controlled to control transmittance.

5. The semitransparent crystalline silicon thin film solar cell of claim 2, further comprising a conductive layer electrically connecting the second transparent electrode to a first transparent electrode of an adjacent cell.
